(19) United States
(12) Patent Application Publication
(10) Pub. No.: US 2019/0212946 A1
(43) Pub. Date: Jul. 11, 2019

(54) DATA STORAGE DEVICE AND OPERATING METHOD THEREOF

(71) Applicant: SK hynix Inc., Gyeonggi-do (KR)

(72) Inventor: Byung Jun KIM, Gyeonggi-do (KR)

(21) Appl. No.: 16/107,111

(22) Filed: Aug. 21, 2018

(30) Foreign Application Priority Data
Jan. 10, 2018 (KR) 10-2018-0003400

(51) Int. Cl. G06F 3/06; G06F 12/02; G11C 16/10; G11C 11/56

(52) U.S. Cl. CPC G06F 3/0659; G06F 3/0656; G06F 3/061; G06F 3/0679; G11C 11/5607; G11C 16/10; G11C 11/5628; G11C 2211/5646; G06F 12/0246

(57) ABSTRACT

A data storage device includes a write data buffer configured to store write data; a hold flag bit map including hold flag bits corresponding to the write data, the hold flag bits being set to values indicating whether to hold the write data; and a processor configured to determine, when a first write command and first write data are received from a host device, whether to hold the first write data in the write data buffer, based on a setting value of a data hold bit included in the first write command, set a hold flag bit corresponding to the first write data to a first value when the first write data is to be held in the write data buffer, and set the hold flag bit to a second value when the first write data is not to be held in the write data buffer.

### CROSS-REFERENCES TO RELATED APPLICATION

The present application claims priority under 35 U.S.C. § 119(a) to Korean patent application number 10-2018-0003400, filed on Jan. 10, 2018, which is incorporated herein by reference in its entirety.

### BACKGROUND

### 1. Technical Field

Various embodiments generally relate to a semiconductor device, and, more particularly, to a data storage device and an operating method thereof.

### 2. Related Art

Recently, the paradigm for the computer environment has been converted into ubiquitous computing so that computer systems can be used anytime and anywhere. Due to this fact, the use of portable electronic devices such as mobile phones, digital cameras, and notebook computers has rapidly increased. In general, such portable electronic device may use a data storage device which in turn uses a memory device for storing data to be used in a portable electronic device.

A data storage device using a memory device provides advantages in that, since there is no mechanical driving part, stability and durability are excellent, an information access speed is high and power consumption is small. Data storage devices having such advantages include a universal serial bus (USB) memory device, memory cards having various interfaces, a universal flash storage (UFS) device, and a solid-state drive (SSD). Due to high consumer demand for improved electronic devices demand for improved data storage devices is also high.

### SUMMARY

Various embodiments are directed to a data storage device with improved read performance and an operating method thereof.

In an embodiment, a data storage device may include: a nonvolatile memory device; a write data buffer configured to temporarily store write data to be stored in the nonvolatile memory device; a hold flag bit map including hold flag bits corresponding to the write data temporarily stored in the write data buffer, the hold flag bits being set to values indicating whether to hold the corresponding write data; and a processor configured to determine, when a first write command and first write data are received from a host device, whether to hold the first write data in the write data buffer, based on a setting value of a data hold bit included in the first write command, set a hold flag bit corresponding to the first write data to a first value when it is necessary to hold the first write data in the write data buffer, and set the hold flag bit corresponding to the first write data to a second value when it is not necessary to hold the first write data in the write data buffer.

In an embodiment, a method for operating a data storage device may include: checking, when a first write command and first write data are received from a host device, a setting value of a data hold bit included in the first write command; determining whether to hold the first write data in a write data buffer, based on the setting value of the data hold bit; and setting a hold flag bit corresponding to the first write data to a first value when it is determined that the first write data is to be held in the write data buffer, and setting the hold flag bit corresponding to the first write data to a second value when it is determined that it is not necessary to hold the first write data in the write data buffer.

In an embodiment, a memory system may include: a memory device; and a controller suitable for buffering, in response to a write request, write data in a buffer and controlling the memory device to store the buffered data. The write request includes a first information representing whether to hold corresponding write data in the buffer and a second information representing whether to delete previously buffered write data from the buffer. The controller selectively sets and releases hold flags respectively corresponding to the buffered write data according to the first and second information, selectively holds the buffered write data according to the hold flags after the memory device stores the buffered write data, and releases, when the buffered write data has a greater size than a threshold, the hold flags corresponding to selected one or more among the buffered write data.

According to various embodiments of the present invention, data to be read-requested from a host device within a short time or data to be read-requested frequently may not be deleted and may be held in a data buffer. Due to this, a read operation speed may be increased and read performance may be improved.

### BRIEF DESCRIPTION OF THE DRAWINGS

FIG. 1 is a simplified block diagram illustrating a configuration of a data storage device according to an embodiment of the present disclosure;

FIG. 2 is a diagram illustrating a configuration of a write command;

FIG. 3 is a diagram illustrating a write data buffer and a hold flag bit map;

FIG. 4A is a diagram illustrating an example in which the size of write data is larger than a hold threshold;

FIG. 4B is a diagram illustrating an example in which first write data is held and second write data is deleted;

FIG. 4C is a diagram illustrating an example in which second write data includes a delete bit for first write data;

FIG. 4D is a diagram illustrating an example in which write commands having data hold bits of a set state are successively received;

FIG. 5 is a flow chart illustrating a method for operating a data storage device, according to an embodiment of the present disclosure;

FIG. 6 is a flow chart illustrating the operating method in the case where a subsequent write command is received in a state in which data is held in the write data buffer;

FIG. 7 is a diagram illustrating an example of a data processing system including a solid-state drive (SSD), according to an embodiment of the present disclosure;

FIG. 8 is a diagram illustrating an example of a controller illustrated in FIG. 7;

FIG. 9 is a diagram illustrating an example of a data processing system including a data storage apparatus, according to an embodiment of the present disclosure;

FIG. 10 is a diagram illustrating an example of a data processing system including a data storage apparatus, according to an embodiment of the present disclosure;

FIG. 11 is a diagram illustrating an example of a network system including a data storage apparatus, according to an embodiment of the present disclosure; and

FIG. 12 is a simplified block diagram illustrating an example of a nonvolatile memory device included in a data storage apparatus according to an embodiment of the present disclosure.

### DETAILED DESCRIPTION

Hereinafter, a data storage device and an operating method thereof will be described below with reference to the accompanying drawings through various examples of embodiments.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

It will be further understood that when an element is referred to as being “connected to”, or “coupled to” another element, it may be directly on, connected to, or coupled to the other element, or one or more intervening elements may be present. In addition, it will also be understood that when an element is referred to as being is “between” two elements, it may be the only element between the two elements, or one or more intervening elements may also be present.

The term “or” as used herein means either one of two or more alternatives but not both nor any combinations thereof.

As used herein, the term “and/or” includes any and all combinations of one or more of the associated listed items.

As used herein, singular forms are intended to include the plural forms as well, unless the context clearly indicates otherwise.

It will be further understood that the terms “includes,” and “including” are used interchangeably in this specification with the open-ended terms “comprises,” and “comprising,” to specify the presence of any stated elements and to not preclude the presence or addition of one or more other non-stated elements.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

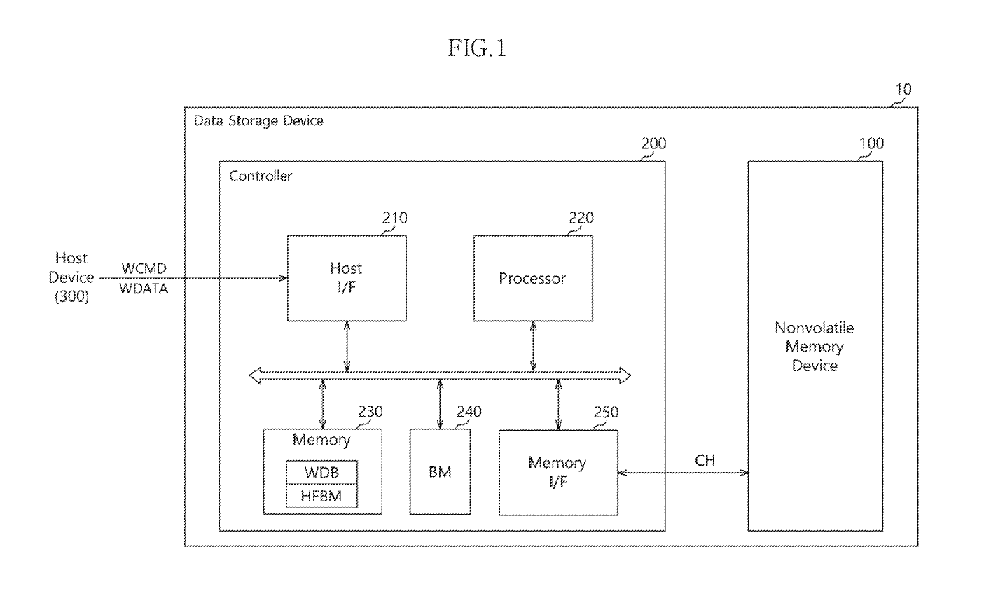

FIG. 1 is a simplified block diagram illustrating an example of the configuration of a data storage device 10, in accordance with an embodiment. In the present embodiment, the data storage device 10 may store data to be accessed by a host device 300 such as a mobile phone, an MP3 player, a laptop computer, a desktop computer, a game player, a TV, an in-vehicle infotainment system, and so forth. The data storage device 10 may also be referred to as a memory system.

The data storage device 10 may be manufactured as any one among various kinds of storage devices suitable for connecting with the host device 300 via a host interface 210 employing a suitable transmission protocol. For example, the data storage device 10 may be configured as any one of various kinds of storage devices such as a solid-state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, a memory stick, and so forth.

The data storage device 10 may be manufactured as any one among various kinds of package types. For example, the data storage device 10 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP), a wafer-level stack package (WSP), and/or the like.

Referring to FIG. 1, the data storage device 10 may include a nonvolatile memory device 100 and a controller 200.

The nonvolatile memory device 100 may operate as the storage medium of the data storage device 10. The nonvolatile memory device 100 may be configured by any one of various types of nonvolatile memory devices such as a NAND flash memory device, a NOR flash memory device, a ferroelectric random-access memory (FRAM) using a ferroelectric capacitor, a magnetic random-access memory (MRAM) using a tunneling magneto-resistive (TMR) layer, a phase change random-access memory (PRAM) using a chalcogenide alloy, and a resistive random-access memory (RERAM) using a transition metal compound.

While it is illustrated in FIG. 1 that the data storage device 10 includes one nonvolatile memory device 100, this is done for illustration purposes only. It is to be noted that in other embodiments, the data storage device 10 may include a plurality of nonvolatile memory devices.

The nonvolatile memory device 100 may include a memory cell array which has a plurality of memory cells respectively disposed at regions where a plurality of bit lines (not shown) and a plurality of word lines (not shown) cross over each other. The memory cell array may include a plurality of planes, and each plane may include a plurality of memory blocks. Each of the plurality of memory blocks may include a plurality of pages.

Each memory cell of the memory cell array may be a single level cell (SLC) storing one bit, a multi-level cell (MLC) capable of storing 2-bit data, a triple level cell (TLC) capable of storing 3-bit data or a quad level cell (QLC) capable of storing 4-bit data. The memory cell array may include at least ones among single level cells, multi-level cells, triple level cells and quad level cells. For example, the memory cell array may include memory cells arranged in a 2-dimensional horizontal structure or memory cells arranged in a 3-dimensional vertical structure.

The controller 200 may include besides the host interface (Host I/F) 210, a processor 220, a memory 230, a buffer manage (BM) 240 and a memory interface (Memory I/F) 250.

The host interface 210 may interface the host device 300 and the data storage device 10. For example, the host interface 210 may communicate with the host device 300 by using any one among standard transmission protocols such as universal serial bus (USB), universal flash storage (UFS), multimedia card (MMC), parallel advanced technology attachment (PATA), serial advanced technology attachment (SATA), small computer system interface (SCSI), serial attached SCSI (SAS), peripheral component interconnection (PCI), PCI express (PCI-E) and/or the like protocols.

The host device 300 may transmit a command and data to the data storage device 10 or receive a response to a command and data from the data storage device 10, through the host interface 210. While it is illustrated in FIG. 1 as an example for the sake of is convenience in explanation that the host device 300 transmits a write command WCMD and write data WDATA to the data storage device 10, it is obvious to a person skilled in the art that the host device 300 may transmit various commands and control signals to the data storage device 10.

The host device 300 may transmit, to the data storage device 10, the write command WCMD including a data hold bit indicating whether to hold currently provided data and a data delete bit indicating whether to delete previously provided data.

FIG. 2 is a diagram illustrating a representation of an example of the configuration of the write command WCMD transmitted from the host device 300.

Referring to FIG. 2, the write command WCMD transmitted from the host device 300 may include operation code information Operation Code indicating that the corresponding command is a command requesting a write operation, a start logical block address Start LBA and an address length LBA Length as location information to perform the write operation, and additional information region Info Region having various informations necessary to perform the operation for the write operation. The data hold bit HB and the data delete bit DB may be included in the additional information region Info Region.

The data hold bit HB has a value indicative of whether to hold in a write data buffer WDB write data WDATA transmitted together with the corresponding write command WCMD. For the sake is of convenience in explanation, in the present embodiment, it is assumed that, if the data hold bit HB has a value of ‘1’, the corresponding write data WDATA of the corresponding write command WCMD, which is currently provided, may not be deleted from and be held in the write data buffer WDB. If the data hold bit HB has a value of ‘0’, the corresponding write data WDATA of the corresponding write command WCMD, which is currently provided, may be deleted from the write data buffer WDB.

The data delete bit DB has a value indicative of whether to delete from the write data buffer WDB previously held write data WDATA before the corresponding write command WCMD, which is currently provided. For the sake of convenience in explanation, in the present embodiment, it is assumed that, if the data delete bit DB has a value of ‘1’, previously held write data WDATA may be deleted from the write data buffer WDB. If the data delete bit DB has a value of ‘0’, previously held write data WDATA may not be deleted from the write data buffer WDB and may be kept held in the write data buffer WDB.

The processor 220 may be configured by a micro control unit (MCU) or a central processing unit (CPU). The processor 220 may process a command transmitted from the host device 300. In order to process the command, the processor 220 may drive an instruction or algorithm of a code type, that is, a software. The software may be loaded in the memory 230. The processor 220 may control the various internal function blocks and the nonvolatile memory device 100.

The memory 230 may be configured by a random-access memory such as a dynamic random-access memory (DRAM) or a static random-access memory (SRAM). The memory 230 may store a software to be driven by the processor 220. Also, the memory 230 may store the data needed to drive the software. Namely, the memory 230 may operate as a working memory of the processor 220.

The memory 230 may temporarily store write data WDATA to be transmitted from the host device 300 to the nonvolatile memory device 100 or read data (not shown) to be read from the nonvolatile memory device 100 and be transmitted to the host device 300. In other words, the memory 230 may operate as a buffer memory.

The memory 230 may include the write data buffer WDB and a hold flag bit map HFBM. While it is illustrated in FIG. 1 for the sake of simplification in illustration that the memory 230 includes the write data buffer WDB, the memory 230 may include a read data buffer which is separated from the write data buffer WDB.

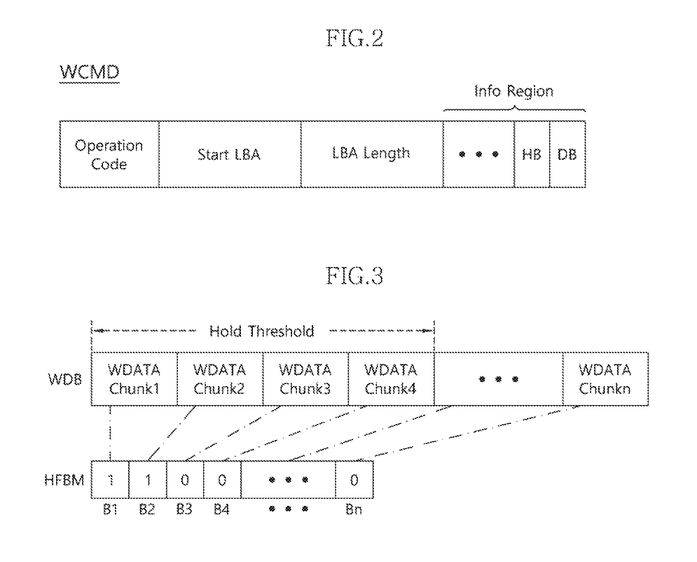

FIG. 3 is a diagram illustrating a representation of an example of the write data buffer WDB and the hold flag bit map HFBM.

Referring to FIG. 3, the write data buffer WDB may be configured to store the write data WDATA transmitted from the host device 300, by the unit of chunk. The hold flag bit map HFBM may include hold flag bits which respectively correspond to the write data chunks WDATA Chunk stored in the write data buffer WDB. For example, if n number of write data chunks WDATA Chunk1 to WDATA Chunkn are stored in the write data buffer WDB, the hold flag bit map HFBM may include respectively corresponding n number of bits B1 to Bn. Here, n may be an integer equal to or greater than 1.

The processor 220 may set or reset the flag bits of the hold flag bit map HFBM based on the data hold bit HB and the data delete bit DB included in the write command WCMD received from the host device 300. For the sake of convenience in explanation, it is assumed that a set flag bit has a value of ‘1’ and a reset flag bit has a value of ‘0’ in the hold flag bit map HFBM.

As shown in FIG. 3, the number of write data chunks capable of being held at the maximum in the write data buffer WDB, that is, a hold threshold may be set in advance. For the sake of convenience in explanation, in the present embodiment, it is assumed that the hold threshold corresponds to four write data chunks WDATA Chunk. It is to be noted that the hold threshold shown in FIG. 3 means not a region but the number of write data chunks (for example, the size of write data).

In an embodiment, the processor 220 may control the nonvolatile memory device 100 to perform, if the write data buffer WDB is full of write data chunks WDATA Chunk, a write operation for the write data chunks WDATA Chunk stored in the write data buffer WDB. In an embodiment, the processor 220 may control the nonvolatile memory device 100 to perform, if the number of the write data chunks WDATA Chunk stored in the write data buffer WDB becomes equal to or greater than a predetermined number, a write operation for the write data chunks WDATA Chunk currently stored in the write data buffer WDB.

The buffer manager 240 may be configured to manage the write data buffer WDB of the memory 230. The buffer manger 240 may manage to hold or delete the write data chunk WDATA Chunk stored in the write data buffer WDB, by referring to the hold flag bit map HFBM. For example, the buffer manager 240 may check, in the hold flag bit map HFBM, the setting value (‘set’ or ‘reset’) of the flag bits corresponding to the respective write data chunks WDATA Chunk stored in the write data buffer WDB, and may selectively hold or delete the write data chunks WDATA Chunk stored in the write data buffer WDB.

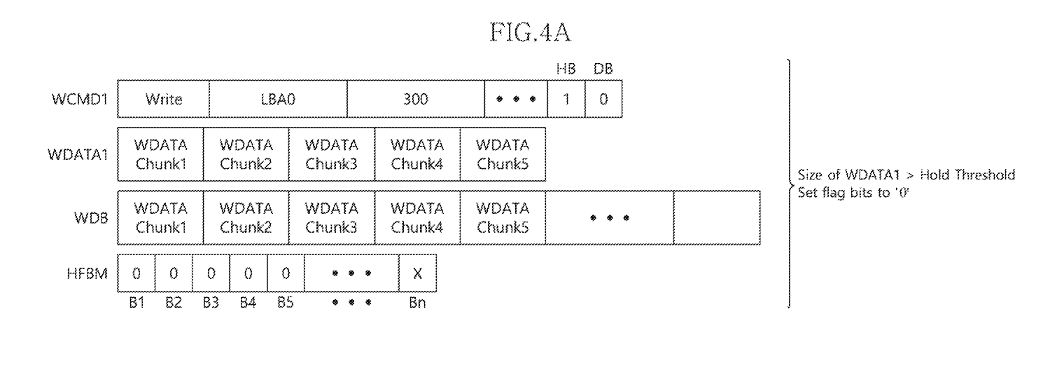

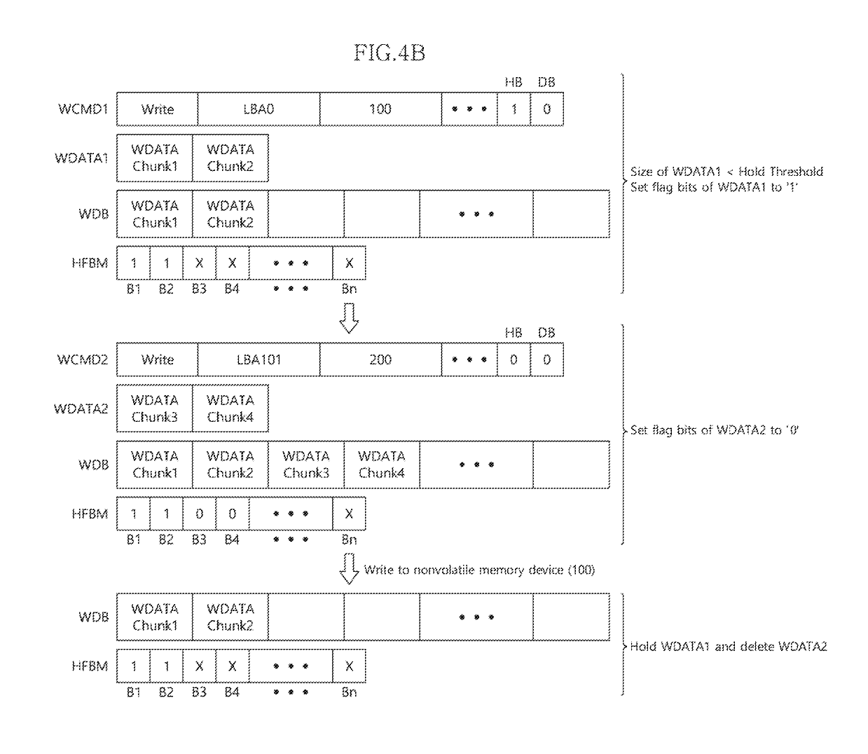

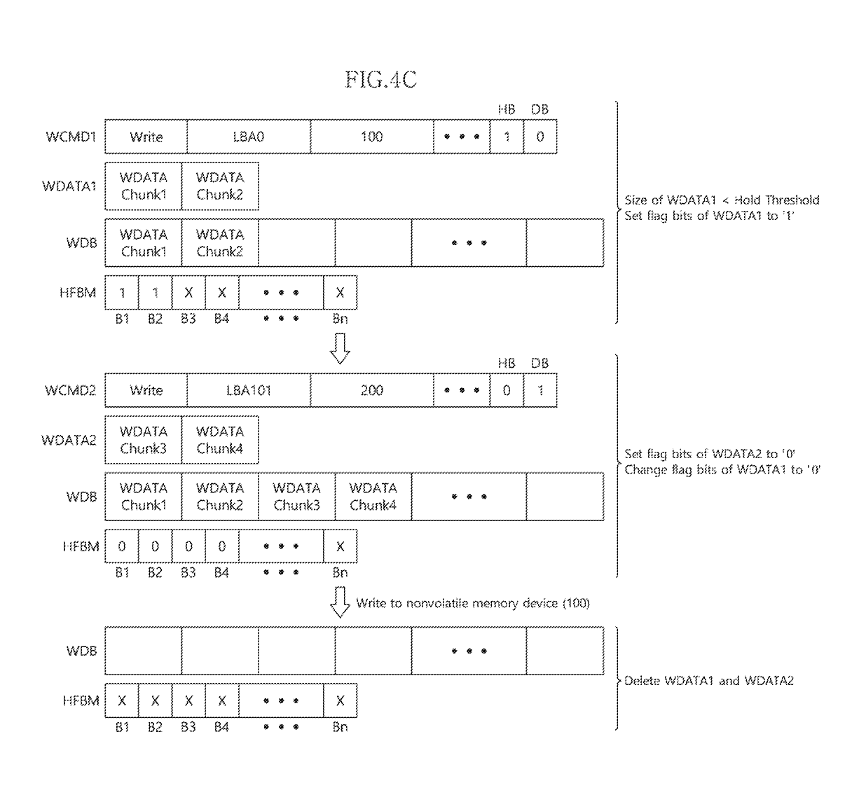

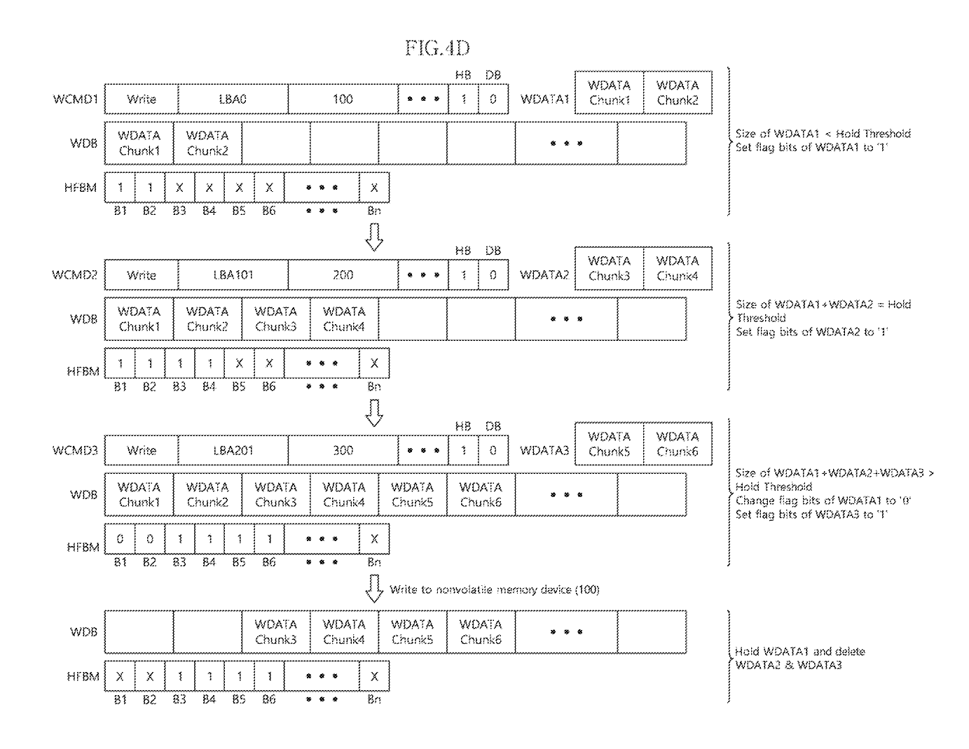

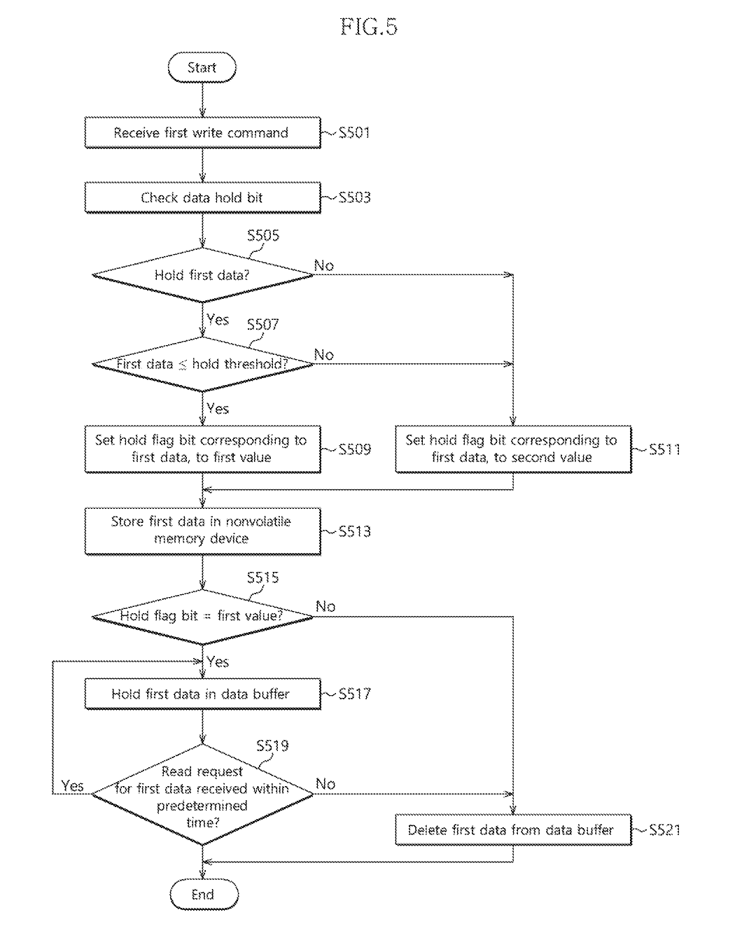

FIG. 4A is a diagram illustrating a representation of an example in which the size of write data WDATA is larger than the hold threshold. For the sake of convenience in explanation, it is assumed that the write data buffer WDB is in an empty state.

As shown in FIG. 4A, as a first write command WCMD1 and first write data WDATA1 are received from the host device 300, the buffer manager 240 may store the first write data WDATA1 in the write data buffer WDB.

The processor 220 may check the data hold bit HB and the data delete bit DB included in the first write command WCMD1. Since the data hold bit HB has a value of ‘1’ and the data delete bit DB has a value of ‘0’, the processor 220 may determine the first write data WDATA1 to be held in the write data buffer WDB, and may compare the size of the first write data WDATA1 with the hold threshold.

As described above, in the described embodiment, the hold threshold corresponds to four write data chunks WDATA Chunk. Since the first write data WDATA1 includes five write data chunks WDATA Chunk1 to WDATA Chunk5, i.e., greater than the hold threshold of four write data chunks, the processor 220 may determine to delete the first write data WDATA1 from the write data buffer WDB and may set the hold flag bits B1 to B5 corresponding to the respective write data chunks WDATA Chunk1 to WDATA Chunk5 of the first write data WDATA1 to have a value of ‘0’.

If performing a write operation corresponding to the first write command WCMD1 is completed, the buffer manager 240 may check by referring to the hold flag bit map HFBM that the hold flag bits 131 to 135 for the respective write data chunks WDATA Chunk1 to WDATA Chunk5 of the first write data WDATA1 are set to have a value of ‘0’, and may delete the write data chunks WDATA Chunk1 to WDATA Chunk5 of the first write data WDATA1 from the write data buffer WDB.

FIG. 4B is a diagram illustrating a representation of an example in which first write data WDATA1 is held and second write data WDATA2 is deleted. For the sake of convenience in explanation, it is assumed that the write data buffer WDB is in an empty state and write unit corresponds to four write data chunks WDATA Chunk. That is, it is assumed that a write operation is performed when four write data chunks WDATA Chunk are stored in the write data buffer WDB.

As shown in FIG. 4B, if a first write command WCMD1 and first write data WDATA1 are received from the host device 300, the buffer manager 240 may store the first write data WDATA1 in the write data buffer WDB.

The processor 220 may check the data hold bit HB and the data delete bit DB included in the first write command WCMD1. Since the data hold bit HB has a value of ‘1’ and the data delete bit DB has a value of ‘0’, the processor 220 may determine the first write data WDATA1 to be held in the write data buffer WDB, and may compare the size of the first write data WDATA1 with the hold threshold.

Since the first write data WDATA1 includes two write data chunks WDATA Chunk1 and WDATA Chunk2, the processor 220 may determine to hold the first write data WDATA1 in the write data buffer WDB, and may set the hold flag bits B1 and B2 corresponding to the respective write data chunks WDATA Chunk1 and WDATA Chunk2 of the first write data WDATA1, to have a value of ‘1’.

Thereafter, if a second write command WCMD2 and second write data WDATA2 are received from the host device 300, the buffer manager 240 may store the second write data WDATA2 in the write data buffer WDB.

The processor 220 may check the data hold bit HB and the data delete bit DB included in the second write command WCMD2. Since the data hold bit HB has a value of ‘0’ and the data delete bit DB has a value of ‘0’, the processor 220 may determine to delete the second write data WDATA1 from the write data buffer WDB due to the data hold bit HB of ‘0’ while determining to still hold the first write data WDATA1 (i.e., the write data chunks WDATA Chunk1 and WDATA Chunk2) in the write data buffer WDB due to the data delete bit DB of ‘0’. Therefore, the processor 220 may set the hold flag bits B3 and B4 corresponding to respective write data chunks WDATA Chunk3 and WDATA Chunk4 of the second write data WDATA2 to have a value of ‘0’.

As the four write data chunks WDATA Chunk1 to WDATA Chunk4 are stored in the write data buffer WDB, the processor 220 may control the nonvolatile memory device 100 to perform a write operation for the first write command WCMD1 and the second write command WCMD2 since it is assumed that a write operation is performed when four write data chunks WDATA Chunk are stored in the write data buffer WDB.

If the write operation for the first write command WCMD1 and the second write command WCMD2 is completed, the buffer manager 240 may check by referring to the hold flag bit map HFBM that the hold flag bits B1 and B2 for the write data chunks WDATA Chunk1 and WDATA Chunk2 of the first write data WDATA1 are set to have a value of ‘1’ and the hold flag bits B3 and B4 for the write data chunks WDATA Chunk3 and WDATA Chunk4 of the second write data WDATA2 are set to have a value of ‘0’. Therefore, the buffer manager 240 may delete the write data chunks WDATA Chunk3 and WDATA Chunk4 of the second write data WDATA2 from the write data buffer WDB and keep holding the write data chunks WDATA Chunk1 and WDATA Chunk2 of the first write data WDATA1.

FIG. 4C is a diagram illustrating a representation of an example in which second write data includes a data delete bit DB for first write data previously stored in the write data buffer WDB. For the sake of convenience in explanation, it is assumed that the write data buffer WDB is in an empty state and a write operation is performed when four le data chunks WDATA Chunk are stored in the write data buffer WDB.

As shown in FIG. 4C, if a first write command WCMD1 and first write data WDATA1 are received from the host device 300, the buffer manager 240 may store the first write data WDATA1 in the write data buffer WDB.

Since the data hold bit HB has a value of ‘1’ and the data delete bit DB has a value of ‘0’, the processor 220 may determine the first write data WDATA1 to be held in the write data buffer WDB, and may compare the size of the first write data WDATA1 with the hold threshold. Since the first write data WDATA1 includes two write data chunks WDATA Chunk1 and WDATA Chunk2, the processor 220 may set the hold flag bits B1 and B2 corresponding to the respective write data chunks WDATA Chunk1 and WDATA Chunk2 of the first write data WDATA1, to have a value of ‘1’.

Thereafter, if a second write command WCMD2 and second write data WDATA2 are received from the host device 300, the buffer manager 240 may store the second write data WDATA2 in the write data buffer WDB. The processor 220 may check the data hold bit HB and the data delete bit DB included in the second write command WCMD2. Since the data hold bit HB has a value of ‘0’ and the data delete bit DB has a value of ‘1’, the processor 220 may determine to delete the second write data WDATA2 from the write data buffer WDB due to the data hold bit HB of ‘0’ while determining to also delete the first write data WDATA1 (i.e., the write data chunks WDATA Chunk1 and WDATA Chunk2) from the write data buffer WDB due to the data delete bit DB of ‘1’. Therefore, the processor 220 may change the hold flag bits B1 and B2 corresponding to the respective data chunks WDATA Chunk1 and WDATA Chunk2 of the first write data WDATA1, to have a value of ‘0’, and may set the hold flag bits B3 and B4 corresponding to the respective write data chunks WDATA Chunk3 and WDATA Chunk4 of the second write data WDATA2, to have a value of ‘0’.

As the four write data chunks WDATA Chunk1 to WDATA Chunk4 are stored in the write data buffer WDB, the processor 220 may control the nonvolatile memory device 100 to perform a write operation for the first write command WCMD1 and the second write command WCMD2 since it is assumed that a write operation is performed when four write data chunks WDATA Chunk are stored in the write data buffer WDB.

If performing of the write operation for the first write command WCMD1 and the second write command WCMD2 is completed, the buffer manager 240 may check by referring to the hold flag bit map HFBM that the hold flag bits B1 to B4 for the write data chunks WDATA Chunk1 to WDATA Chunk4 of the first write data WDATA1 and the second write data WDATA2 are set to have a value of ‘0’. Therefore, the buffer manager 240 may delete the write data chunks WDATA Chunk1 to WDATA Chunk4 of the first and second write data WDATA1 and WDATA2 from the write data buffer WDB.

FIG. 4D is a diagram illustrating a representation of an example in which write commands having data hold bits HB of a set state are successively received. For the sake of convenience in explanation, it is assumed that the write data buffer WDB is in an empty state, hold threshold corresponds to four write data chunks WDATA Chunk and a write operation is performed when six write data chunks WDATA Chunk are stored in the write data buffer WDB.

As shown in FIG. 4D, if a first write command WCMD1, a second write command WCMD2 and a third write command WCMD3, each of which has a data hold bit HB set to a value of ‘1’, are sequentially received from the host device 300, the buffer manager 240 may sequentially store first write data WDATA1, second write data WDATA2 and third write data WDATA3 in the write data buffer WDB. It is assumed that all of the first to third write commands WCMD1 to WCMD3 have the data delete bits DB having a value of ‘0’.

The processor 220 may set, until the second write command WCMD2 is received, all the hold flag bits B1 to B4 corresponding to the first write data WDATA1 and the second write data WDATA2, to a value of ‘1’. Due to this fact, the size of data which is stored in the write data buffer WDB and which is to be held in the write data buffer WDB becomes the same as the hold threshold.

If the third write command WCMD3 is received, the processor 220 may select write data to delete from the write data buffer WDB among the first and second write data WDATA1 and WDATA2 which are currently held in the write data buffer WDB. For example, the processor 220 may select as data to be deleted the old data stored first in the write data buffer WDB, data having a read request count from the host device 300 is small, or data which is not read-requested from the host device 300 within a predetermined time.

In FIG. 4D, it is illustrated as an example that the first write data WDATA1 is selected as data to be deleted. The processor 220 may change the hold flag bits B1 and B2 corresponding to the first write data WDATA1, to have a value of ‘0’, and may set the hold flag bits B5 and B6 corresponding to the third write data WDATA3, to have a value of ‘1’.

As six write data chunks WDATA Chunk1 to WDATA Chunk6 are stored in the write data buffer WDB, the processor 220 may control the nonvolatile memory device 100 to perform a write operation for the first to third write commands WCMD1 to WCMD3.

If the write operation is completed for the first to third write commands WCMD1 to WCMD3, the buffer manager 240 may delete the first write data WDATA1 from the write data buffer WDB and keep holding the second and third write data WDATA2 and WDATA3 in the write data buffer WDB according to the hold flag bit map HFBM.

The host device 300 may transmit, to the data storage device 10, a write command WCMD by including therein the data hold bit HB for data to be read within a short time or data to be read frequently, such that the data may not be deleted from the write data buffer WDB and be held in the write data buffer WDB even after the data is stored in the nonvolatile memory device 100, and the data storage device 10 does not delete and holds the corresponding data in the write data buffer WDB for a time desired by the host device 300. According to this fact, read performance may be improved.

The memory interface 250 may control the nonvolatile memory device 100 according to the control of the processor 220. The memory interface 250 may also be referred to as a memory controller. The memory interface 250 may provide control signals to the nonvolatile memory device 100. The control signals may include a command, an address and so forth, for controlling the nonvolatile memory device 100. The memory interface 250 may provide data to the nonvolatile memory device 100 or may be provided with data from the nonvolatile memory device 100. The memory interface 250 may be coupled with the nonvolatile memory device 100 through a channel CH including one or more signal lines.

FIG. 5 is a representation of an example of a flow chart to assist in the explanation of a method for operating a data storage device, in accordance with an embodiment of the present invention.

In explaining the method for operating a data storage device in accordance with the embodiment, with reference to FIG. 5, reference may also be made to FIGS. 1 to 4A. For the sake of convenience in explanation, it is assumed that the write data buffer WDB is in an empty state.

At step S501, a first write command WCMD1 (see FIG. 4A) may be received as well as the first write data WDATA1 to the data storage device 10 from the host device 300.

At step S503, the processor 220 of the controller 200 included in the data storage device 10 may check the data hold bit HB of the first write command WCMD1 received from the host device 300.

At step S505, the processor 220 may determine, based on the setting value of the data hold bit HB, whether to hold the first write data WDATA1 in the write data buffer WDB. When it is determined that the first data is to be held, the process may proceed to step S507. At the step S507, the processor 220 may determine whether the size of the first data (for example, the number of data chunks for the first data) is equal to or smaller than a predetermined hold threshold. If the size of the first data is equal to or smaller than the predetermined hold threshold, the process may proceed to step S509.

At the step S509, the processor 220 may set hold flag bits corresponding to the first write data WDATA1 in the hold flag bit map HFBM, to have a first value. For example, the first value may be ‘1’.

If it is determined at the step S505 that it is not necessary to hold the first write data WDATA1 or it is determined at the step S507 that the size of the whole data stored in the write data buffer WDB exceeds the hold threshold, the process may proceed to step S511.

At the step S511, the processor 220 may set hold flag bits corresponding to the first write data WDATA1 in the hold flag bit map HFBM, to have a second value. For example, the second value may be ‘0’.

At step S513, the processor 220 may control the first write data WDATA1 to be stored in the nonvolatile memory device 100, that is, may control the nonvolatile memory device 100 to perform a write operation for the first write command WCMD1.

At step S515, the processor 220 may check whether the hold flag bits corresponding to the first data are set to have the first value, by using the buffer manager 240. If it is checked that the hold flag bits corresponding to the first data are set to have the first value, the process may proceed to step S517.

At the step S517, the processor 220 may hold the first data in the write data buffer WDB, by using the buffer manager 240.

If it is checked at the step S515 that the hold flag bits corresponding to the first data are set to have the second value, the process may proceed to step S521.

At step S519, the processor 220 may determine whether a read request for the first data is received from the host device 300 within a predetermined time. If a read request for the first data is received within the predetermined time, the processor 220 may keep holding the first data in the write data buffer WDB by using the buffer manager 240. If a read request for the first data is not received within the predetermined time, the process may proceed to the step S521.

At the step S521, the processor 220 may delete the first data from the write data buffer WDB by using the buffer manager 240.

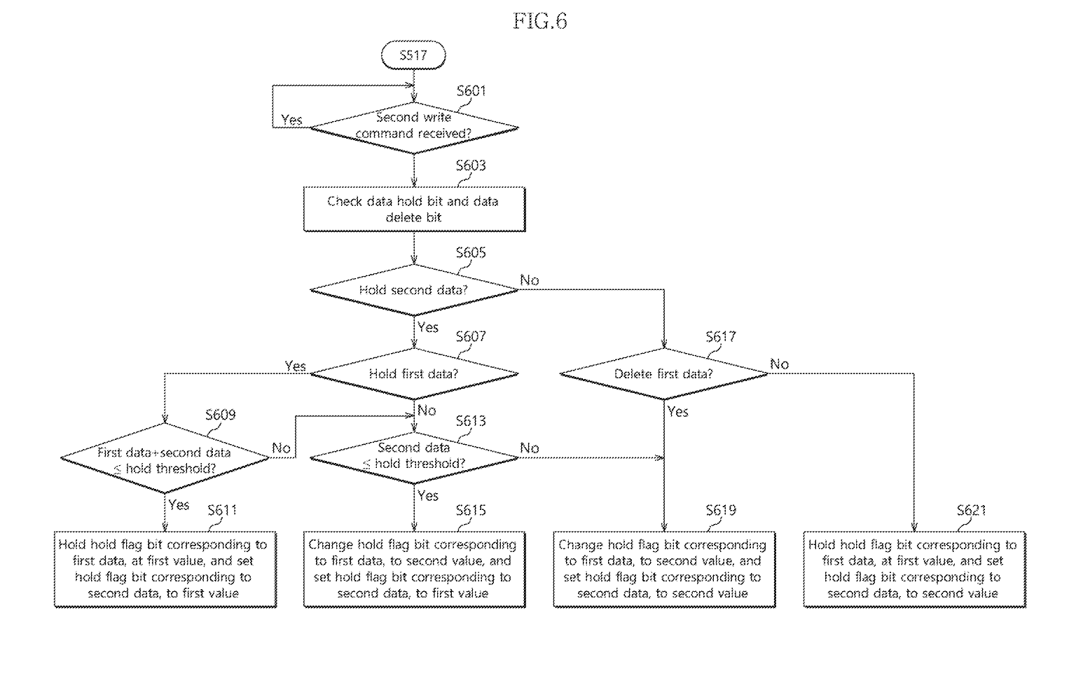

FIG. 6 is a representation of an example of a flow chart to assist in the explanation of the operating method in the case where a subsequent write command is received in a state in which data is held in the write data buffer WDB.

At step S601, a second write command WCMD2 (see FIGS. 4A to 4D) may be received as well as the second write data WDATA2 to the data storage device 10 from the host device 300.

At step S603, the processor 220 may check the data hold bit HB and the data delete bit DB of the second write command WCMD2.

At step S605, the processor 220 may determine, based on the setting value of the data hold bit HB of the second write command WCMD2, whether to hold the second write data WDATA2 in the write data buffer WDB. When it is determined that the second write data WDATA2 is to be held in the write data buffer WDB, the process may proceed to step S607.

At the step S607, the processor 220 may determine, based on the setting value of the data delete bit DB of the second write command WCMD2, whether to hold the first write data WDATA1 being held in the write data buffer WDB. When it is determined that the first write data WDATA1 is to be held, the process may proceed to step S609.

At the step S609, the processor 220 may determine whether the sum of the size of the first write data WDATA1 and the size of the second write data WDATA2 is equal to or smaller than the predetermined hold threshold. If the sum of the size of the first write data WDATA1 and the size of the second write data WDATA2 is equal to or smaller than the predetermined hold threshold, the process may proceed to step S611.

At the step S611, the processor 220 may keep the first value of the hold flag bits corresponding to the first write data WDATA1 in the hold flag bit map HFBM and may set hold flag bits corresponding to the second write data WDATA2 to have the first value.

If it is determined at the step S607 that the first write data WDATA1 is to be deleted or it is determined at the step S609 that the sum of the size of the first write data WDATA1 and the size of the second write data WDATA2 exceeds the predetermined hold threshold, the process may proceed to step S613.

At the step S613, the processor 220 may determine whether the size of the second write data WDATA2 is equal to or smaller than the predetermined hold threshold. If the size of the second write data WDATA2 is equal to or smaller than the predetermined hold threshold, the process may proceed to step S615.

At the step S615, the processor 220 may change the hold flag bits corresponding to the first write data WDATA1 in the hold flag bit map HFBM, to have the second value, and may set hold flag bits corresponding to the second data, to have the first value.

When it is determined at the step S605 that it is not necessary to hold the second data, the process may proceed to step S617.

At the step S617, the processor 220 may determine, based on the setting value of the data delete bit DB of the second write command WCMD2, whether to delete the first write data WDATA1 being held in the write data buffer WDB. When it is determined that the first write data WDATA1 is to be deleted, the process may proceed to step S619.

At the step S619, the processor 220 may change the hold flag bits corresponding to the first write data WDATA1 in the hold flag bit map HFBM, to have the second value, and may set hold flag bits corresponding to the second write data WDATA2, to have the second value.

When it is determined at the step S617 that the first write data WDATA1 is to be held, the process may proceed to step S621.

At the step S621, the processor 220 may keep the first value of the hold flag bits corresponding to the first write data. WDATA1 in the hold flag bit map HFBM, and may set hold flag bits corresponding to the second write data WDATA2, to have the second value.

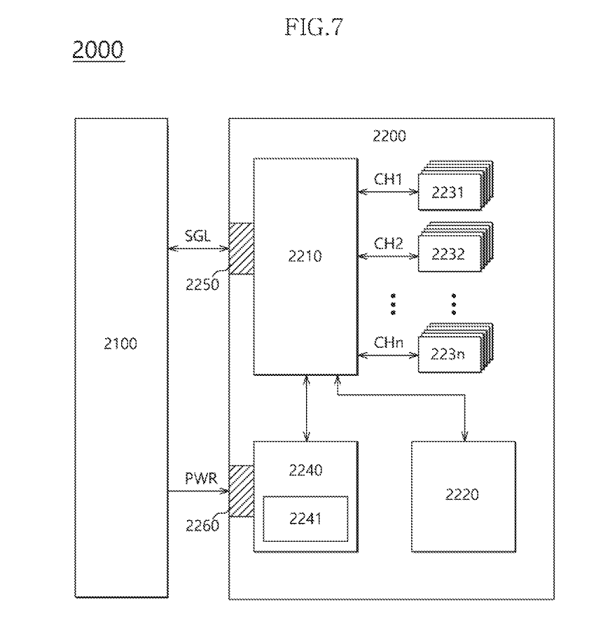

FIG. 7 is a diagram illustrating an example of a data processing system including a solid-state drive (SSD) according to an embodiment. Referring to FIG. 7, a data processing system 2000 may include a host apparatus 2100 and an SSD 2200.

The SSD 2200 may include a controller 2210, a buffer memory device 2220, nonvolatile memory devices 2231 to 223n, a power supply 2240, a signal connector 2250, and a powerconnector 2260.

The controller 2210 may control an overall operation of the SSD 2220.

The buffer memory device 2220 may temporarily store data to be stored in the nonvolatile memory devices 2231 to 223n. The buffer memory device 2220 may temporarily store data read from the nonvolatile memory devices 2231 to 223n. The data temporarily stored in the buffer memory device 2220 may be transmitted to the host apparatus 2100 or the nonvolatile memory devices 2231 to 223n according to control of the controller 2210.

The nonvolatile memory devices 2231 to 223n may be used as a storage medium of the SSD 2200. The nonvolatile memory devices 2231 to 223n may be coupled to the controller 2210 through a plurality of channels CH1 to CHn. The nonvolatile memory devices coupled to the one channel may be coupled to the same signal bus and the same data bus.

The power supply 2240 may provide power PWR input through the power connector 2260 to the inside of the SSD 2200. The power supply 2240 may include an auxiliary power supply 2241. The auxiliary power supply 2241 may supply the power so that the SSD 2200 is normally terminated even when sudden power-off occurs. The auxiliary power supply 2241 may include large capacity capacitors capable of charging the power PWR.

The controller 2210 may exchange a signal SGL with the host apparatus 2100 through the signal connector 2250. The signal SGL may include a command, an address, data, and the like. The signal connector 2250 may be configured of various types of connectors according to an interfacing method between the host apparatus 2100 and the SSD 2200.

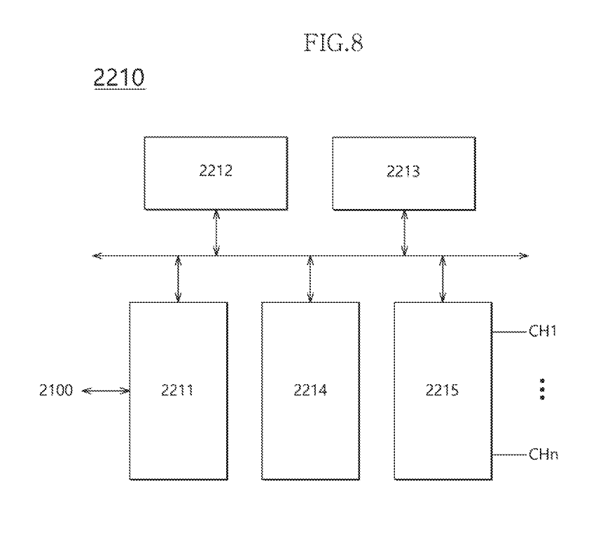

FIG. 8 is a diagram illustrating an example of the controller 2210 of FIG. 7. Referring to FIG. 8, the controller 2210 may include a host interface unit 2211, a control unit 2212, a random-access memory (RAM) 2213, an error correction code (ECC) unit 2214, and a memory interface unit 2215.

The host interface unit 2211 may perform interfacing between the host apparatus 2100 and the SSD 2200 according to a protocol of the host apparatus 2100. For example, the host interface unit 2211 may communicate with the host apparatus 2100 through any one among a secure digital protocol, a universal serial bus (USB) protocol, a multimedia card (MMC) protocol, an embedded MMC (eMMC) protocol, a personal computer memory card international association (PCMCIA) protocol, a parallel advanced technology attachment (PATA) protocol, a serial advanced technology attachment (SATA) protocol, a small computer system interface (SCSI) protocol, a serial attached SCSI (SAS) protocol, a peripheral component interconnection (PCI) protocol, a PCI Express (PCI-E) protocol, and a universal flash storage (UFS) protocol. The host interface unit 2211 may perform a disc emulation function that the host apparatus 2100 recognizes the SSD 2200 as a general-purpose data storage apparatus, for example, a hard disc drive HDD.

The control unit 2212 may analyze and process the signal SGL input from the host apparatus 2100. The control unit 2212 may control operations of internal functional blocks according to firmware and/or software for driving the SDD 2200. The RAM 2213 may be operated as a working memory for driving the firmware or software.

The ECC unit 2214 may generate parity data for the data to be transferred to the nonvolatile memory devices 2231 to 223n. The generated parity data may be stored in the nonvolatile memory devices 2231 to 223n together with the data. The ECC unit 2214 may detect errors for data read from the nonvolatile memory devices 2231 to 223n based on the parity data. When detected errors are within a correctable range, the ECC unit 2214 may correct the detected errors.

The memory interface unit 2215 may provide a control signal such as a command and an address to the nonvolatile memory devices 2231 to 223n according to control of the control unit 2212. The memory interface unit 2215 may exchange data with the nonvolatile memory devices 2231 to 223n according to control of the control unit 2212. For example, the memory interface unit 2215 may provide data stored in the buffer memory device 2220 to the nonvolatile memory devices 2231 to 223n or provide data read from the nonvolatile memory devices 2231 to 223n to the buffer memory device 2220.

FIG. 9 is a diagram illustrating an example of a data processing system including a data storage apparatus according to an embodiment. Referring to FIG. 9, a data processing system 3000 may include a host apparatus 3100 and a data storage apparatus 3200.

The host apparatus 3100 may be configured in a board form such as a printed circuit board (PCB). Although not shown in FIG. 9, the host apparatus 3100 may include internal functional blocks configured to perform functions of the host apparatus 3100.

The host apparatus 3100 may include a connection terminal 3110 such as a socket, a slot, or a connector. The data storage apparatus 3200 may be mounted on the connection terminal 3110.

The data storage apparatus 3200 may be configured in a board form such as a PCB. The data storage apparatus 3200 may refer to a memory module or a memory card. The data storage apparatus 3200 may include a controller 3210, a buffer memory device 3220, nonvolatile memory devices 3231 to 3232, a power management integrated circuit (PMIC) 3240, and a connection terminal 3250.

The controller 3210 may control an overall operation of the data storage apparatus 3200. The controller 3210 may be configured to have the same configuration as the controller 2210 illustrated in FIG. 8.

The buffer memory device 3220 may temporarily store data to be stored in the nonvolatile memory devices 3231 and 3232. The buffer memory device 3220 may temporarily store data read from the nonvolatile memory devices 3231 and 3232. The data temporarily stored in the buffer memory device 3220 may be transmitted to the host apparatus 3100 or the nonvolatile memory devices 3231 and 3232 according to control of the controller 3210.

The nonvolatile memory devices 3231 and 3232 may be used as a storage medium of the data storage apparatus 3200.

The PMIC 3240 may provide power input through the connection terminal 3250 to the inside of the data storage apparatus 3200. The PMIC 3240 may manage the power of the data storage apparatus 3200 according to control of the controller 3210.

The connection terminal 3250 may be coupled to the connection terminal 3110 of the host apparatus 3100. A signal such as a command, an address, and data and power may be transmitted between the host apparatus 3100 and the data storage apparatus 3200 through the connection terminal 3250. The connection terminal 3250 may be configured in various forms according to an interfacing method between the host apparatus 3100 and the data storage apparatus 3200. The connection terminal 3250 may be arranged in any one side of the data storage apparatus 3200.

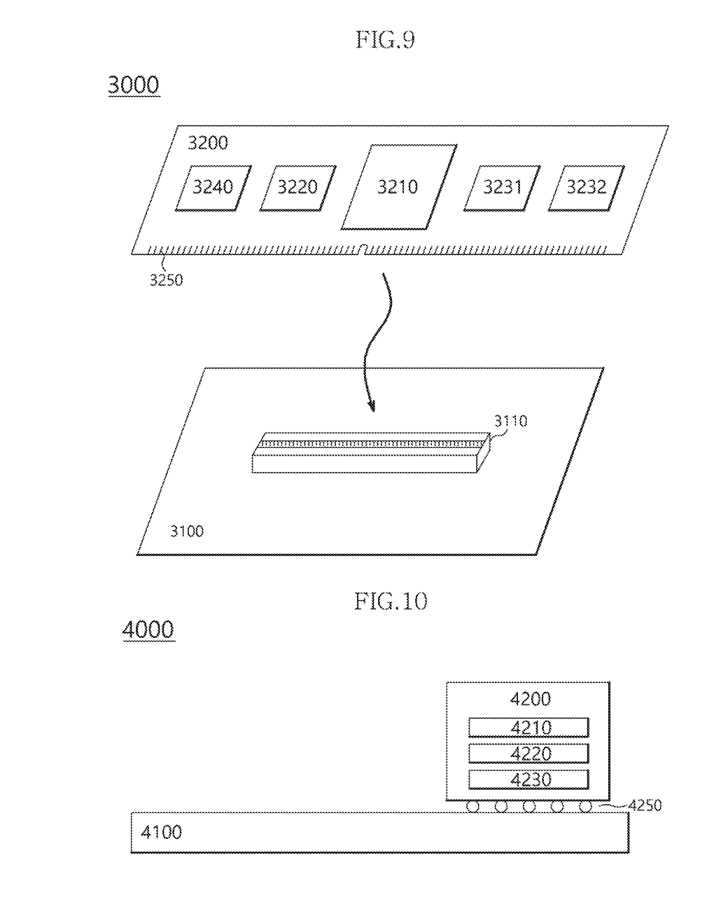

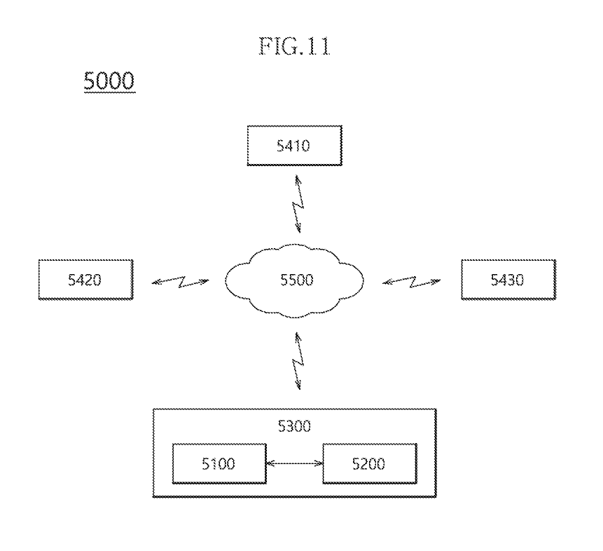

FIG. 10 is a diagram illustrating an example of a data processing system including a data storage apparatus according to an embodiment. Referring to FIG. 10, a data processing system 4000 may include a host apparatus 4100 and a data storage apparatus 4200.

The host apparatus 4100 may be configured in a board form such as a PCB. Although not shown in FIG. 10, the host apparatus 4100 may include internal functional blocks configured to perform functions of the host apparatus 4100.

The data storage apparatus 4200 may be configured in a surface mounting packaging form. The data storage apparatus 4200 may be mounted on the host apparatus 4100 through a solder ball 4250. The data storage apparatus 4200 may include a controller 4210, a buffer memory device 4220, and a nonvolatile memory device 4230.

The controller 4210 may control an overall operation of the data storage apparatus 4200. The controller 4210 may be configured to have the same configuration as the controller 2210 illustrated in FIG. 8.

The buffer memory device 4220 may temporarily store data to be stored in the nonvolatile memory device 4230. The buffer memory device 4220 may temporarily store data read from the nonvolatile memory device 4230. The data temporarily stored in the buffer memory device 4220 may be transmitted to the host apparatus 4100 or the nonvolatile memory device 4230 through control of the controller 4210.

The nonvolatile memory device 4230 may be used as a storage medium of the data storage apparatus 4200.

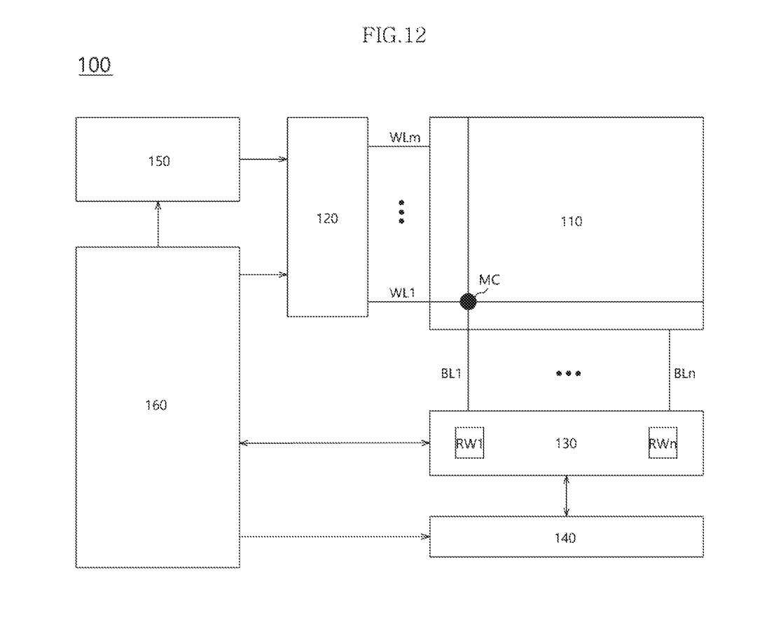

FIG. 11 is a diagram illustrating an example of a network system 5000 including a data storage apparatus according to an embodiment. Referring to FIG. 11, the network system 5000 may include a server system 5300 and a plurality of client systems 5410 to 5430 which are coupled through a network 5500.

The server system 5300 may serve data in response to requests of the plurality of client systems 5410 to 5430. For example, the server system 5300 may store data provided from the plurality of client systems 5410 to 5430. In another example, the server system 5300 may provide data to the plurality of client systems 5410 to 5430.

The server system 5300 may include a host apparatus 5100 and a data storage apparatus 5200. The data storage apparatus 5200 may be configured of the data storage apparatus 10 of FIG. 1, the data storage apparatus 2200 of FIG. 7, the data storage apparatus 3200 of FIG. 9, or the data storage apparatus 4200 of FIG. 10.

FIG. 12 is a simplified block diagram illustrating an example of a nonvolatile memory device included in a data storage apparatus according to an embodiment. Referring to FIG. 12, a nonvolatile memory device 100 may include a memory cell array 110, a row decoder 120, a column decoder 140, a data read/write block 130, a voltage generator 150, and a control logic 160.

The memory cell array 110 may include memory cells MC arranged in regions in which word lines WL1 to WLm and bit lines BL1 to BLn cross to each other.

The row decoder 120 may be coupled to the memory cell array 110 through the word lines WL1 to WLm. The row decoder 120 may operate through control of the control logic 160. The row decoder 120 may decode an address provided from an external apparatus (not shown). The row decoder 120 may select and drive the word lines WL1 to WLm based on a decoding result. For example, the row decoder 120 may provide a word line voltage provided from the voltage generator 150 to the word lines WL1 to WLm.

The data read/write block 130 may be coupled to the memory cell array 110 through the bit lines BL1 to BLn. The data read/write block 130 may include read/write circuits RW1 to RWn corresponding to the bit lines BL1 to BLn. The data read/write block 130 may operate according to control of the control logic 160. The data read/write block 130 may operate as a write driver or a sense amplifier according to an operation mode. For example, the data read/write block 130 may operate as the write driver configured to store data provided from an external apparatus in the memory cell array 110 in a write operation. In another example, the data read/write block 130 may operate as the sense amplifier configured to read data from the memory cell array 110 in a read operation.

The column decoder 140 may operate though control of the control logic 160. The column decoder 140 may decode an address provided from an external apparatus (not shown). The column decoder 140 may couple the read/write circuits RW1 to RWn of the data read/write block 130 corresponding to the bit lines BL1 to BLn and data input/output (I/O) lines (or data I/O buffers) based on a decoding result.

The voltage generator 150 may generate voltages used for an internal operation of the nonvolatile memory device 100. The voltages generated through the voltage generator 150 may be applied to the memory cells of the memory cell array 110. For example, a program voltage generated in a program operation may be applied to word lines of memory cells in which the program operation is to be performed. In another example, an erase voltage generated in an erase operation may be applied to well regions of memory cells in which the erase operation is to be performed. In another example, a read voltage generated in a read operation may be applied to word lines of memory cells in which the read operation is to be performed.

The control logic 160 may control an overall operation of the nonvolatile memory device 100 based on a control signal provided from an external apparatus. For example, the control logic 160 may control an operation of the nonvolatile memory device 100 such as a read operation, a write operation, an erase operation of the nonvolatile memory device 100.

The above embodiments of the present disclosure are illustrative and not limitative. Various alternatives and equivalents are possible. The examples of the embodiments are not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. A data storage device comprising:
a nonvolatile memory device;
a write data buffer configured to temporarily store write data to be stored in the nonvolatile memory device;
a hold flag bit map including hold flag bits corresponding to the write data, temporarily stored in the write data buffer, the hold flag bits being set to values indicating whether to hold the corresponding write data; and
a processor configured to determine, when a first write command and first write data are received from a host device, whether to hold the first write data in the write data buffer, based on a setting value of a data hold bit included in the first write command, is set a hold flag bit corresponding to the first write data to a first value when it is necessary to hold the first write data in the write data buffer, and set the hold flag bit corresponding to the first write data to a second value when it is not necessary to hold the first write data in the write data buffer.

2. The data storage device according to claim 1, wherein, in the case where the setting value of the data hold bit included in the first write command indicates that the first write data be held in the write data buffer, the processor sets the hold flag bit corresponding to the first write data to the first value when a size of the first write data is equal to or smaller than a predetermined hold threshold, and sets the hold flag bit corresponding to the first write data to the second value when the size of the first write data exceeds the predetermined hold threshold.

3. The data storage device according to claim 1, wherein, in the case where the hold flag bit corresponding to the first write data is set to the first value, the processor holds the hold flag bit corresponding to the first write data to the first value when a read request for the first write data is received from the host device within a predetermined time, and changes the hold flag bit corresponding to the first write data to the second value when the read request for the first write data is not received from the host device within the predetermined time.

4. The data storage device according to claim 1, wherein the first write command further includes a data delete bit for requesting whether to delete previous write data being held in the write data buffer.

5. The data storage device according to claim 4, wherein, if a second write command and second write data are received from the host device in a state in which the hold flag bit corresponding to the first write data is set to the first value, the processor determines whether to hold the second write data and whether to delete the first write data, based on a setting value of the data hold bit included in the second write command and a setting value of the data delete bit included in the second write command.

6. The data storage device according to claim 5, wherein, in the case where both the first write data and the second write data are to be held, the processor determines whether a sum of a size of the first write data and a size of the second write data is equal to or smaller than the predetermined hold threshold, and holds the hold flag bit corresponding to the first write data to the first value and sets a hold flag bit corresponding to the second write data to the first value, when the sum of the size of the first write data and the size of the second write data is equal to or smaller than the predetermined hold threshold.

7. The data storage device according to claim 6, wherein, if the sum of the size of the first write data and the size of the second write data exceeds the predetermined hold threshold, the processor determines whether the size of the second write data is equal to or smaller than the predetermined hold threshold, and changes the hold flag bit corresponding to the first write data to the second value and sets the hold flag bit corresponding to the second write data to the first value, when the size of the second write data is equal to or smaller than the predetermined hold threshold.

8. The data storage device according to claim 7, wherein, if the size of the second write data exceeds the predetermined hold threshold, the processor changes the hold flag bit corresponding to the first write data to the second value and sets the hold flag bit corresponding to the second write data to the second value.

9. The data storage device according to claim 5, wherein, in the case where the first write data is to be deleted and the second write data is to be held, the processor determines whether the size of the second write data is equal to or smaller than the predetermined hold threshold, and changes the hold flag bit corresponding to the first write data to the second value and sets the hold flag bit corresponding to the second write data to the first value, when the size of the second write data is equal to or smaller than the predetermined hold threshold.

10. The data storage device according to claim 9, wherein, if the size of the second write data exceeds the predetermined hold threshold, the processor changes the hold flag bit corresponding to the first write data to the second value and sets the hold flag bit corresponding to the second write data to the second value.

11. The data storage device according to claim 5, wherein, in the case where both the first write data and the second write data are to be deleted, the processor changes the hold flag bit corresponding to the first write data to the second value and sets the hold flag bit corresponding to the second write data to the second value.

12. The data storage device according to claim 5, wherein, in the case where the first write data is to be held and the second write data is to be deleted, the processor holds the hold flag bit corresponding to the first write data to the first value and sets the hold flag bit corresponding to the second write data to the second value.

13. A method for operating a data storage device, comprising:
checking, when a first write command and first write data are received from a host device, a setting value of a data hold bit is included in the first write command;
determining whether to hold the first write data in a write data buffer, based on the setting value of the data hold bit; and
setting a hold flag bit corresponding to the first write data to a first value when it is determined that the first write data is to be held in the write data buffer, and setting the hold flag bit corresponding to the first write data to a second value when it is determined that it is not necessary to hold the first write data in the write data buffer.

14. The method according to claim 13, wherein whether a size of the first write data is equal to or smaller than a predetermined hold threshold is determined when it is determined that the first write data is to be held in the write data buffer, and the hold flag bit corresponding to the first write data is set to the first value when the size of the first write data is equal to or smaller than the predetermined hold threshold.

15. The method according to claim 13, further comprising, in the case where the hold flag bit corresponding to the first write data is set to the first value:
determining whether a read request for the first write data is received from the host device within a predetermined time; and
holding the hold flag bit corresponding to the first write data to the first value when the read request for the first write data is received within the predetermined time, and changes the hold flag bit corresponding to the first write data to the second value when the read request for the first write data is not received within the predetermined time.

16. The method according to claim 13, further comprising, in the case where the hold flag bit corresponding to the first write data is set to the first value:
determining, if a second write command and second write data are received from the host device, whether to hold the second write data and whether to delete the first write data, by checking a setting value of the data hold bit included in the second write command and a setting value of a data delete bit included in the second write command.

17. The method according to claim 16, further comprising, when it is determined that both the first write data and the second write data are to be held:
determining whether a sum of a size of the first write data and a size of the second write data is equal to or smaller than the predetermined hold threshold; and
holding the hold flag bit corresponding to the first write data to the first value and setting a hold flag bit corresponding to the second write data to the first value, when the sum of the size of the first write data and the size of the second write data is equal to or smaller than the predetermined hold threshold.

18. The method according to claim 17, further comprising, when the sum of the size of the first write data and the size of the second write data exceeds the predetermined hold threshold:
determining whether the size of the second write data is equal to or smaller than the predetermined hold threshold; and
changing the hold flag bit corresponding to the first write data to the second value and setting the hold flag bit corresponding to the second write data to the first value, when the size of the second write data is equal to or smaller than the predetermined hold threshold.

19. The method according to claim 18, wherein, if the size of the second write data exceeds the predetermined hold threshold, the hold flag bit corresponding to the first write data is changed to the second value, and the hold flag bit corresponding to the second write data is set to the second value.

20. The method according to claim 16, further comprising, when it is determined that the first write data is to be deleted and the second write data is to be held:
determining whether the size of the second write data is equal to or smaller than the predetermined hold threshold; and
changing the hold flag bit corresponding to the first write data to the second value and setting the hold flag bit corresponding to the second write data to the first value, when the size of the second write data is equal to or smaller than the predetermined hold threshold.

21. The method according to claim 20, wherein, if the size of the second write data exceeds the predetermined hold threshold, the hold flag bit corresponding to the first write data is changed to the zc second value, and the hold flag bit corresponding to the second write data is set to the second value.

22. The method according to claim 16, wherein, when it is determined that both the first write data and the second write data are to be deleted, the hold flag bit corresponding to the first write data is changed to the second value, and the hold flag bit corresponding to the second write data is set to the second value.

23. The method according to claim 16, wherein, when it is determined that the first write data is to be held and the second write data is to be deleted, the hold flag bit corresponding to the first write data is held to the first value, and the hold flag bit corresponding to the second write data is set to the second value.
